(19) United States
(12) Patent Application Publication
(10) Pub. No.: US 2023/0163782 A1
(43) Pub. Date: May 25, 2023

(54) DATA COMPRESSION SYSTEM USING CONCATENATION IN STREAMING

(71) Applicants: SIMÃO AZNAR FILHO, Rio de Janeiro (BR); CARLA DOLEZEL TRINDADE, Rio de Janeiro (BR); ALLAN KARDEC DUAILIBE BARROS FILHOS, São Luis (BR); CAIO MAGNO AGUIAR DE CARVALHO, São Luis (BR); LETICIA CABRAL CORREIRA, São José de Ribamar (BR)

(72) Inventors: CARLA DOLEZEL TRINDADE, Rio de Janeiro (BR); ALLAN KARDEC DUAILIBE BARROS FILHOS, São Luis (BR)

(21) Appl. No.: 17/828,224

(22) Filed: May 31, 2022

(30) Foreign Application Priority Data
Nov. 19, 2021 (BR) 1020210232900

(51) Int. Cl. H03M 7/30

(52) U.S. Cl. CPC H03M 7/30

(57) ABSTRACT

The present disclosure refers to a data compression system developed to serve several areas, providing a compressed form of information with the purpose of occupying less bytes than the original form, obtaining as a result, the transmission and maintenance of a compressed form of information and requiring less time and space, compared to performing the same functions with the original form of information, that is, using files already compressed by traditional methods and reordering them data in order to achieve new bit gains breaking the compression limit of methods already universally known, being for this purpose constituted by the encoding process, streaming concatenation process, decompression process and deconcatenation process.

### CROSS REFERENCE TO RELATED APPLICATIONS

This application claims the benefit and takes priority from the Brazilian Patent Application No. 1020210232900 filed on Nov. 19, 2021, the contents of which are herein incorporated by reference.

### APPLICATION FIELD

The Field of Application of this Data Compression System is broad and vast and allows its application in the most diverse sectors of the economy, industry, agriculture and other activities, in which the transmission and storage of data is necessary, where a compressed representation of the data is required.

### Purposes

The purpose of the Data Compression System presented here is to treat a compressed form of a file in order to occupy fewer bits than the original form, obtaining, as a result, a new compressed form of the file for transmission or storage, requiring less time and memory, that is, using files already compressed by traditional methods in order to achieve new gains in bits, thus breaking the limit of compression methods already universally known.

### Problems to Solve

As is common knowledge among technicians in the area, one of the biggest problems of computer systems in the area of information processing is to represent a large file that takes up more storage space and requires more transmission time, for a smaller file that occupies less storage space. storage and requires less transmission time, a fact that is obtained with the processing of compression and decompression operations.

### Technological Progress

The data compression process corresponds to a more efficient restructuring, and it works by recognizing the repeated information in the file, replacing it with a code every time that information appears in the file.

Specifically, data compression is the act of reducing the space occupied by data on a given device. This operation is performed through several compression algorithms, reducing the amount of bytes to represent a data, being this data an image, text or any file, that is, it consists of the use of a set of methods and other practical details aiming to reduce the space stored in secondary or even primary memory units of a computer system.

The disadvantages of the above mentioned state of the art are overcome and additional advantages are provided through the Data Compression System, which uses Streaming Concatenation to recode the data in order to achieve new bit gains, breaking the compression limit of methods already universally known.

### DESCRIPTION OF THE FIGURES

To obtain a total and complete view of how the Data Compression System is now on screen, follow the attached flowcharts to which references are made as follows:

FIG. 1: Represents Operational Flowchart of the Coding System;

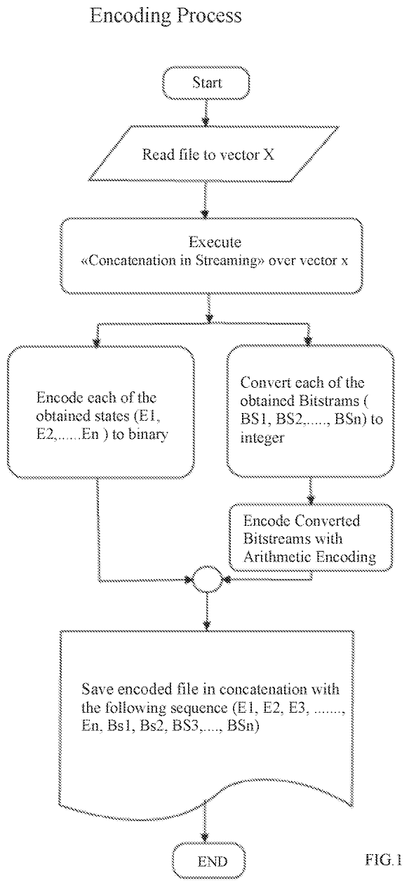

FIG. 2: Corresponds to the Operational Flowchart of the Streaming Concatenation Process:

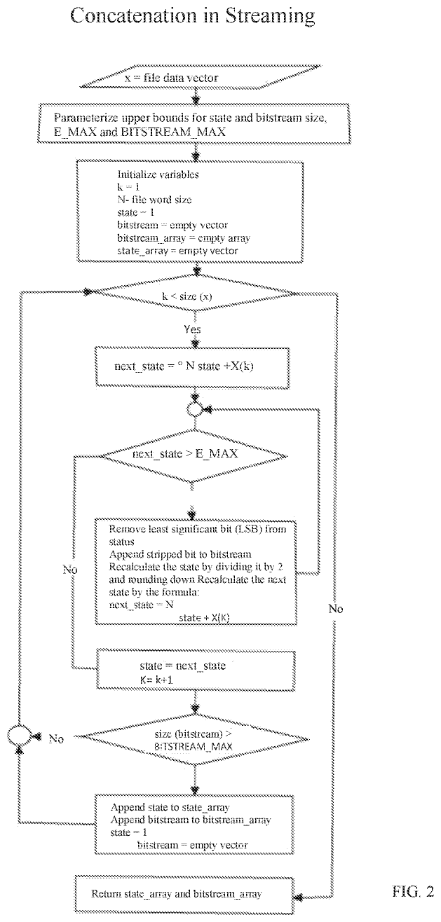

FIG. 3: Refers to the Decompression Process and

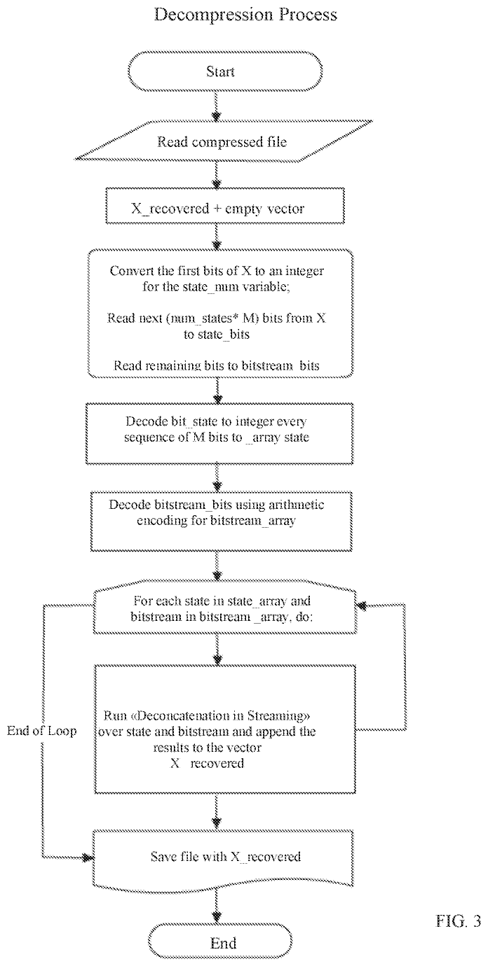

FIG. 4: Shows the Operational Flowchart of the Streaming Deconcatenation Process.

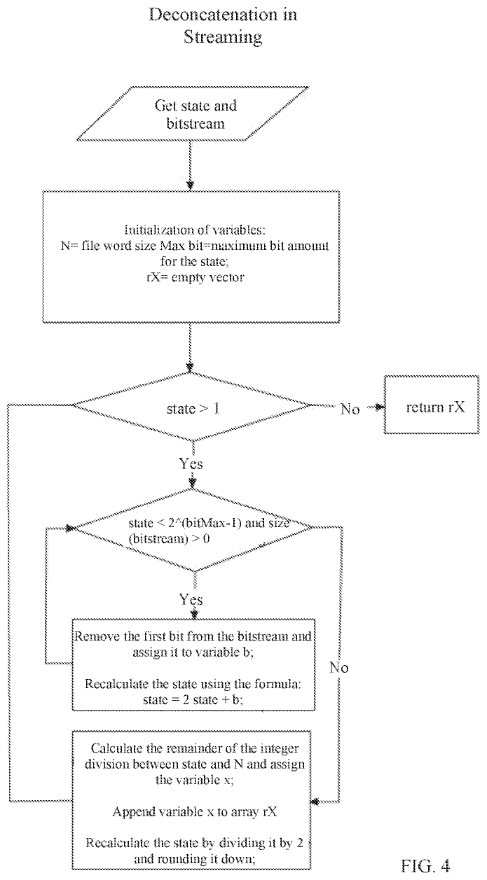

### DESCRIPTION OF THE INVENTION

As can be seen from the flowcharts that accompany and form an integral part of this report, the Data Compression System was developed to perform data compression/decompression, using files already compressed by traditional methods, which are reordered in order to achieve new gains. of bits breaking the compression limit of already universally known methods.

In this way and to meet the intended purposes, the Data Compression System consists of two processes, Data Compression and Data Decompression, the mentioned processes being constituted by two operations each, which correspond to the Encoding Process, the Concatenation in Streaming, these two regarding data compression and the Decompression Process and Deconcatenation Process regarding data decompression.

The Encoding Process comprises the steps of reading the tile for vector “X”; execution of the concatenation in streaming over the vector “X”; encoding each of the obtained states to binary; converting each of the Bitstreams to integer; encoding the converted Bitstreams with arithmetic encoding and saving the encoded file in a specific sequence.

The Streaming Concatenation process, where “X” corresponds to the file's data vector; the upper limits are set for State and Bitstream size; start variables, k/n/state/bitstream; the size of the variable “k” is defined; insert the word size of the file; the maximum size for state and for E MAX is fixed; the least significant state bit is removed, the removed bit is appended to the bitstream, the state is recalculated by dividing by two and the next state is recalculated by the formula next_state=N*state+X(k): check state=next_state k=k+1; analyze the size (bitstream)>BITSTREAM_MAX; append state to state_array and bitstream to bitstream_array and return state_array and bitstream_array.

The Decompression Process comprises reading the compressed file; recovery of “X”_recovered+empty vector; converting the first bits of “X” into an integer for the variable num_states, reading the next ones (num_states* M) bits of “X” for state bits and reading the remaining bits for bitstream_bits; decoding bit_state to integer every sequence of M bits to array_state; bitstream_bits decoding using arithmetic decoding for bitstream_array; execution of “Deconcatenation in Streaming” on state and bitstream, appending the results to the vector “X” recovered and save file with “X”recovered.

The Deconcatenation Process comprises receiving state and bitstream; initialization of N/bitMax rX variables; state >1 is entered; it is approved; insert state <2\hat{ } (biteMax−1) and size (bitstream) >0; it is approved; remove the first bit from the bitstream and assign it to variable b, recalculate the state using the formula state=2*state+b and calculate the remainder of the integer division between state and N and assign variable x, appended if the variable x to the array rX and the state is recalculated by dividing it by 2 and rounding it.

It is noteworthy that, although it borrows its name from Streaming services, the method is not related to such services since the meaning of the entry “streaming” means “transmission”. The name comes from the way the data is presented after applying the method, in a transmission queue.

The Data Compression System in question is based on the following parameters: 020 Initially, the compressed file is read in a chosen bit precision, soon after, this data will be concatenated until a certain limit is reached. If the limit is reached, the surplus will be stored in a variable, called BitStream, which will not be a simple difference to be stored, but the Least Significant Bit (MSB) will compose the BitStream.

So, each time the concatenation operation exceeds the defined limit, the MSB will be removed and saved. However, BitStream is also associated with a limiting condition, it cannot exceed a certain size.

At the end of applying the concatenation, the original file is converted into a set of States (the part of the Concatenation that does not exceed the proposed limit) and BitStream.

The State will be encoded in a fixed bit precision, while the BitStream will be compressed with a statistical algorithm, the Arithmetic Method was used for this. In this way, the Data Compression System achieved a reduction of 1% to 20% in relation to compressed files, which in practice means that the savings of the first used compression method—HUffman, Arithmetic, ANS, etc—can be increased, if the described technique is used in sequence.

### CONCLUSION

It can be seen from all that has been described and illustrated that it is a Data Compression System Using Concatenation in Streaming, which fits within the rules that govern the Patent of Invention because it incorporates development whose compression results reach a range understood between 1% and 20% in relation to compressed files, deserving for what has been described and illustrated, the requested privilege.

1. DATA COMPRESSION SYSTEM USING CONCATENATION IN STREAMING, developed to serve several areas, providing a compressed form of information in order to occupy less bytes than the original form, obtaining as a result, the transmission and storage of a compressed form of information and requiring less time and space, being characterized by being constituted by the encoding process, streaming concatenation process, decoding process and d+concatenation. process.

2. DATA COMPRESSION SYSTEM USING CONCATENATION IN STREAMING according to claim 1, characterized by the encoding process comprising the steps of reading the file for vector “X”; execution of the concatenation in streaming over the vector “X”; encoding each of the obtained states to binary; converting each of the Bitstreams to integer; converting the converted Bitstreams with arithmetic encoding and saving the encoded file in concatenation in a specific sequence.

3. DATA COMPRESSION SYSTEM USING CONCATENATION IN STREAMING according to claim 1, characterized by the process of concatenation in streaming the “X” corresponds to the data vector of the file; the upper limits are parameterized for State and for Bitstream size; start variables, kin/state/bitstream; the size of the variable “k” is defined; insert the word size of the file; the maximum size for state and for E MAX is fixed; The least significant state bit is removed, the removed bit is appended to the bitstream, the state is recalculated by dividing by two and the next state is recalculated by the formula next state=N*state+X(k); check state=next state k=k +1, analyze the size (bitstream)>BITSTREAM_MAX; append state to state_array and bitstream to bitstream_array and return state_array and bitstream_array.

4. DATA COMPRESSION SYSTEM USING CONCATENATION IN STREAMING according to claim 1, characterized by the decompression process comprising reading the compressed file; recovery of X_recovered+empty vector; converting the first bits of X to an integer for the num_states variable, reading the next (num_states*M) bits of X to state_bits and reading the remaining bits to bitstrearn_bits; decoding bit_state to integer each sequence of M bits to array state; bitstream bits decoding using arithmetic decoding for bitstream array; execution of “Deconcatenation in Streaming” on state and bitstream, appending the results to the X_recovered vector and saving file with X_recovered.

5. DATA COMPRESSION SYSTEM USING CONCATENATION IN STREAMING according to claim 1, characterized by the deconcatenation process comprises receiving state and bitstream; initialization of N/bitMax rX variables; state >1 is entered; it is approved; insert state <2 \hat{ } (bitMax−1) and size (bitstream) >0; it is approved; remove the first bit from the bitstream and assign it to variable b, recalculate the state using the formula state=2*state b and calculate the remainder of the integer division between state and N and assign variable x, appended if the variable x to the array rX and the state is recalculated by dividing it by 2 and rounding it.
